(19) United States
(12) Patent Application Publication
(10) Pub. No.: US 2026/0271471 A1
(43) Pub. Date: Sep. 10, 2026

(54) LIGHT EMITTING MODULE AND LIGHT SYSTEM INCLUDING THE SAME

(71) Applicant: SEOUL VIOSYS CO., LTD., Ansan-si (KR)

(72) Inventors: Jina LEE, Ansan-si (KR); Jiho KIM, Ansan-si (KR)

(73) Assignee: SEOUL VIOSYS CO., LTD., Ansan-si (KR)

(21) Appl. No.: 19/551,786

(22) Filed: Feb. 27, 2026

Related U.S. Application Data
(60) Provisional application No. 63/766,543, filed on Mar. 4, 2025.

(51) Int. Cl. H10H 29/85; F21S 41/153; F21S 43/14; H10D 80/30; H10H 20/858; H10H 29/20; H10H 29/49; H10W 72/20; H10W 90/10

(52) U.S. Cl. CPC H10H 29/8581; H10D 80/30; H10H 20/8581; H10H 20/8585; H10H 29/20; H10H 29/49; H10H 29/8585; H10W 72/222; H10W 72/234; H10W 72/235; H10W 72/252; H10W 72/255; H10W 72/265; H10W 90/10; F21S 41/153; F21S 43/14

(57) ABSTRACT

A light emitting module includes a substrate; a light emitting device disposed on the substrate; and a driving device disposed on the substrate, wherein the light emitting device includes: a light emitting layer configured to generate light; and a light emitting device joint disposed between the light emitting layer and the substrate to fix the light emitting layer to the substrate, wherein the driving device includes: a control circuit layer configured to control the light emitting device; and a driving device joint disposed between the control circuit layer and the substrate to fix the control circuit layer to the substrate.

### TECHNICAL FIELD

The present disclosure relates to a light emitting module and a light emitting system including the same.

### BACKGROUND OF INVENTION

Light emitting diodes (LEDs) are widely used in light emitting systems. Alight emitting diode converts an electric signal into a form of light such as infrared rays, visible light, and ultraviolet rays using characteristics of a compound semiconductor.

As light efficiency of the light emitting diode increases, a light emitting device is being applied to various fields including a display device, lighting equipment, a vehicle, and the like.

Recently, a need for a light emitting module including a light emitting device irradiating light displaying various information is increasing.

### CONTENTS OF INVENTION

### Problems to be Solved by Invention

Embodiments of the present disclosure provide a light emitting module capable of forming a three-dimensional image such as a figure, text, or a video.

Embodiments also provide a light emitting module in which at least one of the light emitting device and the driving device may be prevented from being damaged or positionally misaligned by heat.

### Means for Solving Problems

In accordance with an aspect of the present disclosure, there may be provided a light emitting module including: a substrate; a light emitting device disposed on the substrate; and a driving device disposed on the substrate, wherein the light emitting device includes: a light emitting layer generating light; and a light emitting device joint disposed between the light emitting layer and the substrate to fix the light emitting layer to the substrate, wherein the driving device includes: a control circuit layer controlling the light emitting device; and a driving device joint disposed between the control circuit layer and the substrate to fix the control circuit layer to the substrate, wherein the light emitting device joint includes a primary component having a predetermined content and additive elements having a content smaller than the content of the primary component, wherein the driving device joint includes a primary component having a predetermined content and additive elements having a content smaller than the content of the primary component, and wherein a content of the additive elements included in the light emitting device joint is different from a content of the additive elements included in the driving device joint.

Further, there may be provided the light emitting module in which the content of the additive elements included in the light emitting device joint is greater than the content of the additive elements included in the driving device joint.

Further, there may be provided the light emitting module in which the primary component of the light emitting device joint includes Sn, the additive elements of the light emitting device joint include Bi, the primary component of the driving device joint includes Sn, and the additive elements of the driving device joint include Ag and Cu.

Further, there may be provided the light emitting module in which a melting point of the light emitting device joint is lower than a melting point of the driving device joint.

Further, there may be provided the light emitting module in which the content of the additive elements included in the light emitting device joint is smaller than the content of the additive elements included in the driving device joint.

Further, there may be provided the light emitting module in which the primary component of the light emitting device joint includes Au, the additive elements of the light emitting device joint include Sn, the primary component of the driving device joint includes Sn, and the additive elements of the driving device joint include Bi.

Further, there may be provided the light emitting module in which the primary component of the light emitting device joint includes Sn, the additive elements of the light emitting device joint include Ag and Cu, the primary component of the driving device joint includes Sn, and the additive elements of the driving device joint include Bi.

Further, there may be provided the light emitting module in which a melting point of the light emitting device joint is higher than a melting point of the driving device joint.

Further, there may be provided the light emitting module in which thermal conductivity of the light emitting device joint and thermal conductivity of the driving device joint are different from each other.

Further, there may be provided a light emitting module including: a substrate; a light emitting device disposed on the substrate and configured to emit light; and a driving device disposed on the substrate, wherein the driving device includes: a control circuit layer for controlling the light emitting device; and a driving device joint disposed between the control circuit layer and the substrate to fix the control circuit layer to the substrate, wherein the driving device joint includes: a first driving device bonding layer connected to the substrate; and a second driving device bonding layer disposed between the first driving device bonding layer and the control circuit layer, wherein the first driving device bonding layer includes a primary component having a predetermined content and additive elements having a predetermined content, wherein the second driving device bonding layer includes a primary component having a predetermined content and additive elements having a predetermined content, and wherein a content of the additive elements included in the first driving device bonding layer is greater than a content of the additive elements included in the second driving device bonding layer.

Further, there may be provided the light emitting module in which the first driving device bonding layer surrounds at least a portion of the second driving device bonding layer.

Further, there may be provided the light emitting module in which the driving device further includes a driving electrode pad disposed between the control circuit layer and the driving device joint, and an upper side of the first driving device bonding layer and an upper side of the second driving device bonding layer are in contact with the driving electrode pad.

Further, there may be provided the light emitting module in which the first driving device bonding layer and the second driving device bonding layer are formed integrally.

Further, there may be provided the light emitting module in which the primary component of the second driving device bonding layer includes Sn, the additive elements of the second driving device bonding layer include at least one of Ag, Cu, Pb, and Sb, the primary component of the first driving device bonding layer includes Sn, and the additive elements of the first driving device bonding layer include Bi, In, or Pb.

Further, there may be provided the light emitting module in which a melting point of the first driving device bonding layer is lower than a melting point of the second driving device bonding layer.

Further, there may be provided the light emitting module in which a content of Sn in the first driving device bonding layer is smaller than a content of Sn in the second driving device bonding layer.

Further, there may be provided the light emitting module in which the light emitting device includes: a light emitting layer for generating light; and a light emitting device joint disposed between the light emitting layer and the substrate to fix the light emitting layer to the substrate, wherein the light emitting device joint includes a primary component having a predetermined content and additive elements having a predetermined content, and wherein the content of the additive elements included in the first driving device bonding layer is greater than a content of the additive elements included in the light emitting device joint.

Further, there may be provided the light emitting module in which the driving device further includes a driving electrode pad disposed between the control circuit layer and the first driving device bonding layer, wherein the driving electrode pad includes: a first driving electrode layer connected to the control circuit layer; and a second driving electrode layer disposed below the first driving electrode layer and in contact with the second driving device bonding layer, and wherein the second driving device bonding layer and the second driving electrode layer include the same material.

Further, there may be provided a light emitting module including: a substrate; and a light emitting device disposed on the substrate, wherein the light emitting device includes: a light emitting layer for generating light; and a light emitting device joint disposed between the light emitting layer and the substrate to fix the light emitting layer to the substrate, wherein the light emitting device joint includes: a first light emitting device bonding layer disposed on the substrate; and a second light emitting device bonding layer disposed between the first light emitting device bonding layer and the light emitting layer, wherein the first light emitting device bonding layer includes a primary component having a predetermined content and additive elements having a predetermined content, wherein the second light emitting device bonding layer includes a primary component having a predetermined content and additive elements having a predetermined content, and wherein a content of the additive elements included in the first light emitting device bonding layer is greater than a content of the additive elements included in the second light emitting device bonding layer.

Further, there may be provided the light emitting module including: a driving device disposed on the substrate, wherein the driving device includes: a control circuit layer for controlling the light emitting device; and a driving device joint disposed between the control circuit layer and the substrate to fix the control circuit layer to the substrate, wherein the driving device joint includes a primary component having a predetermined content and additive elements having a predetermined content, and wherein the content of the additive elements included in the first light emitting device bonding layer is greater than a content of the additive elements included in the driving device joint.

### Effects of Invention

According to an embodiment of the present disclosure, when heat is applied to any one of the light emitting device and the driving device for repair, the other of the light emitting device and the driving device is prevented from being detached from the substrate or positionally misaligned.

Furthermore, according to an embodiment of the present disclosure, when heat is applied to any one of the driving device and the light emitting device, the other of the driving device and the light emitting device is prevented from being damaged or broken by the heat.

Furthermore, an embodiment of the present disclosure has an effect of facilitating repair of the driving device and the light emitting device.

### BRIEF DESCRIPTION OF DRAWINGS

FIG. 1 is a perspective view of a first example of a light emitting system according to a first embodiment of the present disclosure.

FIG. 2 is a perspective view of a second example of the light emitting system according to the first embodiment of the present disclosure.

FIG. 3 is a plan view of a first example of a light emitting module included in the light emitting system according to the first embodiment of the present disclosure.

FIG. 4 is a perspective view of a second example of the light emitting module included in the light emitting system according to the first embodiment of the present disclosure.

FIG. 5 is a cross-sectional view of the light emitting module according to the first embodiment of the present disclosure.

FIG. 6 is an SEM photograph of a driving device of the light emitting module of FIG. 5.

FIG. 7 is an SEM photograph of a driving device joint of a driving device of a light emitting module included in a light emitting system according to a second embodiment of the present disclosure.

FIG. 8 is an enlarged view enlarging a light emitting device joint of a light emitting device of a light emitting module included in a light emitting system according to a third embodiment of the present disclosure.

### SPECIFIC CONTENTS FOR EMBODYING INVENTION

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions.

Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting module 10 according to a first embodiment of the present disclosure and a light emitting system 1 including the same will be described.

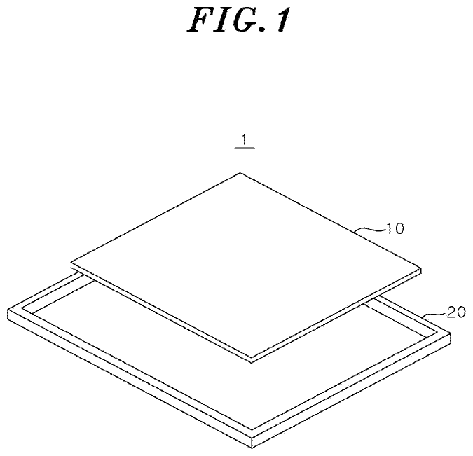

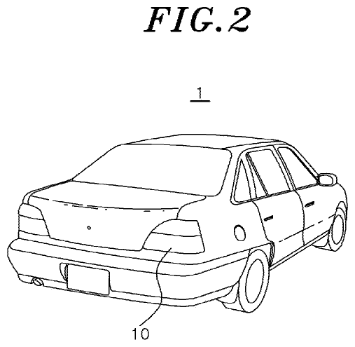

The light emitting system 1 may be the display device of FIG. 1 or the vehicle lamp of FIG. 2, but the present disclosure is not limited thereto. The light emitting system 1 may include a light emitting module 10 and a frame 20. Furthermore, a plurality of light emitting modules 10 may be included according to a size of the light emitting system 1.

The light emitting system 1 shown in FIG. 1 is a display device, and may include one or more light emitting modules 10 including a plurality of light emitting devices 200 to be described later. The light emitting system 1 may display information, and output various visual contents.

The frame 20 may be disposed outside the light emitting system 1. Electric wiring may be added to one region of the frame 20, thereby electrically connecting the light emitting system 1 to an external power source and controlling an operation of the light emitting system 1 according to an electric signal. Furthermore, the light emitting system 1 may be controlled according to an external signal, being driven in various manners.

The frame 20 may serve to reinforce the strength of the light emitting system 1, and may be made of a material having higher strength than a substrate 100 of the light emitting module 10 to be described later. Such a frame 20 may also be used as a structural support connecting different light emitting modules 10. Various materials may be used for the frame 20 according to mechanical strength, processability, and the like. As an example, the frame 20 may include a metal material such as aluminum, stainless steel, and copper. In another embodiment, the frame 20 may include a polymer material such as polycarbonate, acrylic, polyamide, and ABS, carbon fiber reinforced plastic, glass fiber reinforced plastic, or ceramics.

Furthermore, the frame 20 may be manufactured in a form surrounding the light emitting module 10 to reinforce the strength of the light emitting system 1, but the present disclosure is not limited thereto. The frame 20 may be disposed on one surface of the light emitting module 10 to reduce an area of the light emitting system 1.

Furthermore, the light emitting system 1 may further include a diffusion plate and a plurality of optical sheets. A display panel may be disposed on one surface of the optical sheets. The display panel is not particularly limited. For example, the display panel may be a liquid crystal display panel including a liquid crystal layer. Furthermore, a gate driving PCB supplying a driving signal to a gate line and a data driving PCB supplying a driving signal to a data line may be provided at an edge of the display panel.

The light emitting system 1 may include not only the display device but also a vehicle light source. The light emitting system 1 may include a smart headlamp requiring zone-based driving. Such a light emitting system 1 may realize a clear projection image by reducing cross-talk for each projection area.

Furthermore, the light emitting module 10 may display text, a symbol, an image, or a video. Furthermore, the light emitting module 10 may be mounted on a vehicle. The light emitting module 10 may be included in a backup lamp, a headlamp, a rear lamp, a tail lamp, and the like. Furthermore, the light emitting module 10 mounted on the vehicle may emit red-based light, yellow-based light, or white-based light, thereby displaying information such as a stop signal or text to the outside.

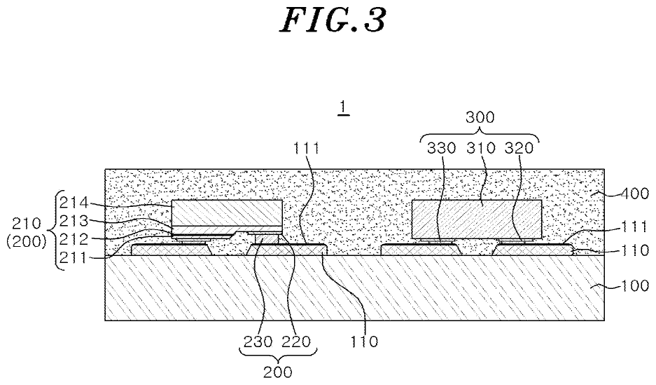

Further referring to FIGS. 3 to 5, the light emitting module 10 may include the substrate 100, the light emitting device 200, the driving device 300, and a molding layer 400.

The light emitting device 200 and the driving device 300 may be disposed on the substrate 100. For example, the substrate 100 may be a printed circuit board (PCB) on which an electric circuit is printed. Furthermore, the substrate 100 may be a thin-film transistor (TFT) backplane. The substrate 100 may be made of a metal material having thermal conductivity, such as Cu and Al. However, this is merely an example, and the substrate 100 may include at least one of insulating materials such as FR1, CEM-1, FR-4, PMMA, PCT, and PPA, thereby preventing a short circuit between respective circuits. Here, FR1 is a material in which a copper foil and a laminated paper are stacked, and CEM-1 is a material in which a copper foil, a glass fiber fabric, a laminated paper, and a glass fiber fabric are sequentially stacked. Furthermore, FR-4 is a material in which a copper foil and a glass fiber woven fabric or glass fiber fabric are stacked. In addition, the substrate 100 may include ceramics such as alumina (Al₂O₃), aluminum nitride (AlN), and ZTA (Zirconia Toughened Alumina). A substrate electrode 110 may be formed on such a substrate 100.

A plurality of substrate electrodes 110 may be formed, being disposed on an upper surface of the substrate 100 to be electrically connected to any one of the light emitting device 200 and the driving device 300. For example, each of the plurality of substrate electrodes 110 may be an electric circuit or an electrode pattern formed on the upper surface of the substrate 100. The substrate electrodes 110 may include at least one of Cu, Zn, Au, Ni, Al, Mg, Cd, Be, W, Mo, Si, Ag, and Fe having electric conductivity, or an alloy composed of some of these, thereby increasing thermal and electric conductivity. Furthermore, a plating layer 111 may be formed on an upper surface of the substrate electrodes 110. The plating layer 111 may be disposed on the upper surface of the substrate electrodes 110. For example, the plating layer 111 may include Sn, Ag, Au, Ni, and the like.

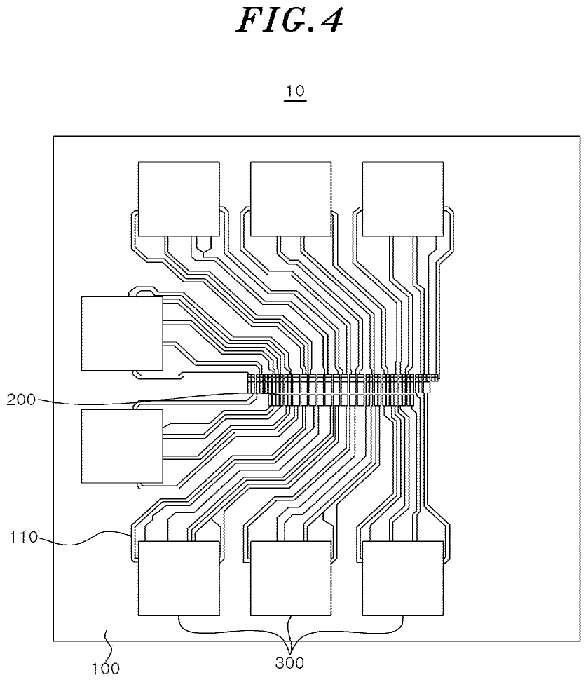

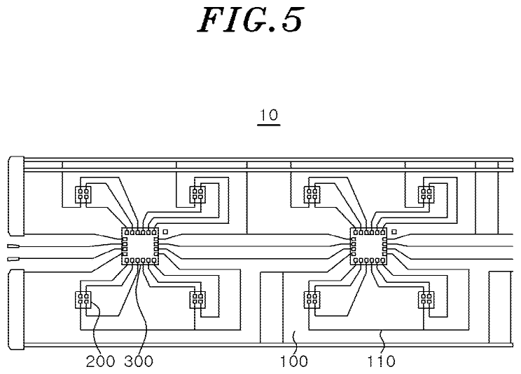

The light emitting device 200 may be disposed on the substrate 100 and may emit light. For example, the light emitting device 200 may emit blue light, green light, red light, white light, ultraviolet (UV) light, or the like. The light emitting device 200 may be electrically connected to a substrate electrode 110 of the substrate 100 and may receive power from an external source through an electrical circuit to emit light. The light emitting device 200 may be disposed to be spaced apart from the driving device 300. In one example, referring to FIG. 4, the light emitting device 200 may be spaced apart from a plurality of driving devices 300, being disposed inside the plurality of driving devices 300. In another example, referring to FIG. 5, a plurality of light emitting devices 200 may be spaced apart from the driving device 300, being formed to surround the driving device 300. Separately disposing the driving device 300 and the light emitting device 200 from each other may lower the difficulty of a manufacturing process of each joint.

The light emitting device 200 may include a light emitting layer 210, a light emitting electrode pad 220, a light emitting device joint 230, and a light transmitting layer 240.

The light emitting layer 210 may generate light. The electrically connected light emitting electrode pad 220 may be disposed below the light emitting layer 210. Such a light emitting layer 210 may include a first conductivity type semiconductor layer 211, an active layer 212, and a second conductivity type semiconductor layer 213.

The first conductivity type semiconductor layer 211 is a semiconductor layer having a polarity opposite to that of the second conductivity type semiconductor layer 213. The first conductivity type semiconductor layer 211 may include n-type impurities (e.g., Si, Ge, Sn). In this case, the first conductivity type semiconductor layer 211 may be an n-type semiconductor layer. However, this is merely an example, and the first conductivity type semiconductor layer 211 may include p-type impurities.

The active layer 212 may be stacked on the first conductivity type semiconductor layer 211. In other words, the active layer 212 may be located between the first conductivity type semiconductor layer 211 and the second conductivity type semiconductor layer 213. Furthermore, the active layer 212 may be disposed to be biased toward one side relative to the center of the thickness of the light emitting device 200. A vertical length of the first conductivity type semiconductor layer 211 may be formed larger than a vertical length of the second conductivity type semiconductor layer 213 by such an active layer 212.

The second conductivity type semiconductor layer 213 may be stacked on the active layer 212. The second conductivity type semiconductor layer 213 may include p-type impurities (e.g., Mg, Sr, Ba), and in this case, the second conductivity type semiconductor layer 213 may be a p-type semiconductor layer. However, this is merely an example, and the second conductivity type semiconductor layer 213 may include n-type impurities. Light generated in the active layer 212 may pass through the second conductivity type semiconductor layer 213 and be emitted to the outside.

The light emitting electrode pad may be disposed below the light emitting layer 210, being electrically connected to the light emitting layer 210. In other words, the light emitting electrode pad 220 may be connected to the first conductivity type semiconductor layer 211 or the second conductivity type semiconductor layer 213. The light emitting layer 210 may generate light by electricity applied from the light emitting electrode pad 220. For example, the light emitting electrode pad 220 may include Sn, Ag, Au, Ni, and the like.

The light emitting device joint 230 may fix the light emitting device 200 to the substrate 100. Such a light emitting device joint 230 may be connected to the light emitting electrode pad 220 and the substrate electrode 110 of the substrate 100. For example, the light emitting device joint 230 may be a metal joint such as solder.

Furthermore, the light emitting device joint 230 may be made of an alloy. In other words, the light emitting device joint 230 may include a primary component and additive elements formed at a predetermined ratio. The light emitting device joint 230 may include a primary component having a predetermined first content and additive elements having a second content smaller than the first content.

For example, the light emitting device joint 230 may be an alloy including a primary component such as tin (Sn) or gold (Au) and additive elements such as Bi, In, Pb, Sb, Sn, Ag, and Cu for lowering a melting point. The primary component and the additive elements of the light emitting device joint 230 are described in detail below.

Such a light emitting device joint 230 may have a predetermined melting point. The melting point of the light emitting device joint 230 may be formed differently from a melting point of a driving device joint 330 to be described later. Thermal conductivity of the light emitting device joint 230 may be different from thermal conductivity of the driving device joint 330. In other words, the thermal conductivity of the light emitting device joint 230 may be formed higher than the thermal conductivity of the driving device joint 330, thereby improving reliability of the light emitting device 200. The light emitting device joint 230 may include a smaller number of metal layers than the driving device joint 330. Alternatively, the light emitting device joint 230 may be formed to have a lower thickness than the driving device joint 330. Alternatively, the light emitting device joint 230 may include materials having higher thermal conductivity than the driving device joint 330. However, the present disclosure is not limited thereto, and the thermal conductivity of the light emitting device joint 230 may be lower than the thermal conductivity of the driving device joint 330.

The light transmitting layer 240 may be stacked on the second conductivity type semiconductor layer 213. The light transmitting layer 240 may be an insulating or conductive substrate, and may be an insulating or conductive substrate joined by bonding. Furthermore, the light transmitting layer 240 may be an insulating or conductive substrate for growing the first conductivity type semiconductor layer 211, the active layer 212, and the second conductivity type semiconductor layer 213. For example, the light transmitting layer 240 may include at least one of a silicon carbide substrate, a silicon substrate, a gallium nitride substrate, an aluminum nitride substrate, a sapphire substrate, and an insulation patterned sapphire substrate (IPSS).

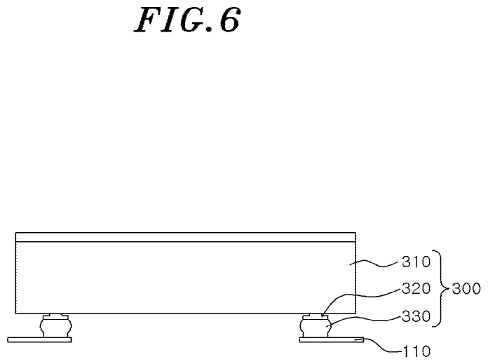

Further referring to FIG. 6, the driving device 300 may be disposed on the substrate 100, controlling the light emitting device 200 to generate light in the light emitting device 200. The driving device 300 may be electrically connected to the substrate electrode 110 of the substrate 100, receiving electricity from the outside through an electric circuit to control the light emitting device 200. Such a driving device 300 may include a control circuit layer 310, a driving electrode pad 320, and the driving device joint 330.

The control circuit layer 310 may control an operation of the light emitting device 200. The control circuit layer 310 may be electrically connected to the light emitting device 200 through the driving electrode pad 320 and the substrate electrode 110 of the substrate 100. The control circuit layer 310 may control the operation of the light emitting device 200 through an electric signal.

The driving electrode pad 320 may be electrically connected to the control circuit layer 310. The driving electrode pad 320 may be disposed between the control circuit layer 310 and the driving device joint 330. For example, the driving electrode pad 320 may include Cu, Au, Ag, Al, Ni, W, and the like.

The driving device joint 330 may fix the driving device 300 to the substrate 100. The driving device joint 330 may be electrically connected to the driving electrode pad 320 and the substrate electrode 110 of the substrate 100. The driving device joint 330 may be a metal joint. As an example, the driving device joint 330 may be solder.

Furthermore, the driving device joint 330 may be made of an alloy. In other words, the driving device joint 330 may include a primary component and additive elements formed at a predetermined ratio. The driving device joint 330 may include a primary component having a predetermined third content and additive elements having a fourth content smaller than the third content. The fourth content included in the driving device joint 330 may be formed differently from the second content included in the light emitting device joint 230.

For example, the driving device joint 330 may be an alloy including a primary component such as tin (Sn) or gold (Au) and additive elements such as Bi, In, Pb, Sb, Sn, Ag, and Cu for lowering a melting point. Such a driving device joint 330 may have a predetermined melting point. The driving device joint 330 and the light emitting device joint 230 may be made of alloys having different ratios. The driving device joint 330 and the light emitting device joint 230 may include different metals. Through this, the melting point of the driving device joint 330 and the melting point of the light emitting device joint 230 may be formed differently from each other, lowering a difficulty of a process during rework.

Hereinafter, a case will be described where a weight percent (wt %) of the second content of the additive elements in a composition ratio of the primary component and the additive elements of the light emitting device joint 230 is higher than a weight percent of the fourth content of the additive elements in a composition ratio of the primary component and the additive elements of the driving device joint 330. In other words, the second content may be greater than the fourth content.

When the weight percent of the second content of the additive elements of the light emitting device joint 230 is higher than the weight percent of the fourth content of the additive elements of the driving device joint 330, the melting point of the light emitting device joint 230 may be lower than the melting point of the driving device joint 330. For example, the melting point of the light emitting device joint 230 may be in a range of 110° C. to 190° C. Furthermore, the melting point of the driving device joint 330 may be in a range of 210° C. to 280° C.

The light emitting device joint 230 may include a primary component Sn and additive elements having a low melting point, such as bismuth (Bi), indium (In), silver (Ag), or lead (Pb), making the melting point of the light emitting device joint 230 lower than the melting point of the driving device joint 330. As a first example, the light emitting device joint 230 may be a metal compound including from 50 wt % to 65 wt % of a primary component Sn and from 35 wt % to 50 wt % of an additive element Bi. As a second example, the light emitting device joint 230 may be a metal compound including from 46 wt % to 55 wt % of a primary component Sn and from 45 wt % to 54 wt % of an additive element In. As a third example, the light emitting device joint 230 may be a metal compound including from 55 wt % to 65 wt % of a primary component Sn and from 35 wt % to 45 wt % of an additive element Pb.

Furthermore, the driving device joint 330 may include a primary component Sn or Au and additive elements Pb, Sb, Ag, or Sn. As an example, the driving device joint 330 may be a metallic compound including, as a primary component, 95 wt % to 97 wt % of Sn, and additive elements including 2 wt % to 3 wt % of Ag and 0.5 wt % to 2 wt % of Cu. As another example, the driving device joint 330 may be a metallic compound including, as a primary component, 75 wt % to 85 wt % of Au, and additive elements including 15 wt % to 25 wt % of Sn.

By virtue of the light emitting device joint 230 and the driving device joint 330, when heat is applied to increase the temperature in order to repair the driving device 300 and the light emitting device 200, the light emitting device joint 230 may melt before the driving device joint 330, such that the light emitting device 200 may be detached from the substrate 100 first. In other words, the driving device 300 may be repaired after the light emitting device 200 is repaired first. In addition, when the light emitting device 200 is detached, heat may be prevented from being transferred to the driving device 300, thereby preventing damage or breakage of the driving device 300.

Hereinafter, a case will be described where the weight percent (wt %) of the second content of the additive elements in the composition ratio of the primary component and the additive elements of the light emitting device joint 230 is smaller than the weight percent of the fourth content of the additive elements in the composition ratio of the primary component and the additive elements of the driving device joint 330. In other words, the second content may be smaller than the fourth content.

When the weight percent of the second content of the additive elements of the light emitting device joint 230 is lower than the weight percent of the fourth content of the additive elements of the driving device joint 330, the melting point of the light emitting device joint 230 may be higher than the melting point of the driving device joint 330. The melting point of such a light emitting device joint 230 may be in a range of 210° C. to 280° C. Furthermore, the melting point of the driving device joint 330 may be in a range of 110° C. to 190° C.

The light emitting device joint 230 may include a primary component Au or Sn and at least one of additive elements Pb, Sb, Ag, Cu, and Sn, forming the melting point of the light emitting device joint 230 higher than the melting point of the driving device joint 330. As a first example, the light emitting device joint 230 may be a metallic compound including, as a primary component, 95 wt % to 97.5 wt % of Sn, and additive elements including 2 wt % to 3 wt % of Ag and 0.5 wt % to 2 wt % of Cu. As a second example, the light emitting device joint 230 may be a metallic compound including, as a primary component, 85 wt % to 95 wt % of Sn, and an additive element including 5 wt % to 15 wt % of Pb. As a third example, the light emitting device joint 230 may be a metallic compound including, as a primary component, 90 wt % to 97 wt % of Sn, and an additive element including 3 wt % to 10 wt % of Sb. As a fourth example, the light emitting device joint 230 may be a metallic compound including, as a primary component, 95 wt % to 98 wt % of Sn, and an additive element including 2 wt % to 5 wt % of Ag. As a fifth example, the light emitting device joint 230 may be a metallic compound including, as a primary component, 75 wt % to 85 wt % of Au, and an additive element including 15 wt % to 25 wt % of Sn.

Furthermore, the driving device joint 330 may include a primary component Sn and additive elements Bi, In, or Pb. As a first example, the light emitting device joint 230 may be a metallic compound including, as a primary component, 50 wt % to 65 wt % of Sn, and an additive element including 35 wt % to 50 wt % of Bi. As a second example, the light emitting device joint 230 may be a metallic compound including, as a primary component, 46 wt % to 55 wt % of Sn, and an additive element including 45 wt % to 54 wt % of In. As a third example, the light emitting device joint 230 may be a metallic compound including, as a primary component, 55 wt % to 65 wt % of Sn, and an additive element including 35 wt % to 45 wt % of Pb.

By such a light emitting device joint 230 and a driving device joint 330, when applying heat to the driving device 300 for repair, shifting of the position of the light emitting device 200 is minimized, protecting the light emitting device 200 from heat.

The molding layer 400 may be disposed on the substrate 100, covering the light emitting device 200 and the driving device 300. Light generated in the light emitting device 200 may be transmitted through the molding layer 400 and be emitted to the outside. The molding layer 400 may prevent the substrate electrode 110, the light emitting device 200, and the driving device 300 from being detached or peeled off from the substrate 100. The molding layer 400 may include a material or a configuration for diffusing light generated in the light emitting device 200 or changing a wavelength of light.

Hereinafter, an operation and an effect of the light emitting system 1 including the light emitting module 10 according to the first embodiment of the present disclosure will be described.

Light may be generated in the light emitting device 200 by control of the driving device 300 of the light emitting system 1 including the light emitting module 10 according to the first embodiment of the present disclosure. Light generated in the light emitting device 200 may pass through the molding layer 400 to be emitted to the outside.

Since the melting point of the light emitting device joint 230 of the light emitting device 200 and the melting point of the driving device joint 330 of the driving device 300 may be formed differently from each other, when heat is applied to any one of the light emitting device 200 and the driving device 300 for repair, the other of the light emitting device 200 and the driving device 300 may be prevented from being detached from the substrate 100 or inclined.

Furthermore, since the melting point of the light emitting device joint 230 of the light emitting device 200 and the melting point of the driving device joint 330 of the driving device 300 may be formed differently from each other, the driving device 300 and the light emitting device 200 may be sequentially repaired by applying heat.

Furthermore, since the melting point of the light emitting device joint 230 of the light emitting device 200 and the melting point of the driving device joint 330 of the driving device 300 may be formed differently from each other, when heat is applied to any one of the driving device 300 and the light emitting device 200, the other of the driving device 300 and the light emitting device 200 may be prevented from being broken or damaged by heat.

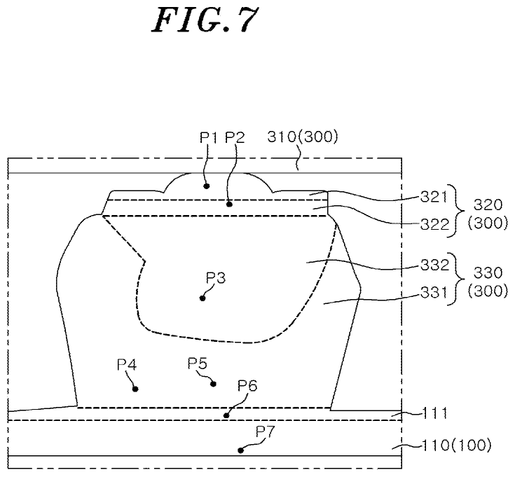

Hereinafter, referring to FIG. 7, the light emitting module 10 according to a second embodiment of the present disclosure and the light emitting system 1 including the same will be described.

In describing the second embodiment, there is a difference in that the driving electrode pad 320 includes a first driving electrode layer 321 and a second driving electrode layer 322, and the driving device joint 330 includes a first driving device bonding layer 331 and a second driving device bonding layer 332, and the description will focus on such differences.

The first driving electrode layer 321 may be stacked on the second driving electrode layer 322 and may be connected to the control circuit layer 310. The first driving electrode layer 321 may include at least one of Cu, Au, Ag, Al, and Ni. For example, an arbitrary region P1 of the first driving electrode layer 321 may include 90 wt % to 100 wt % of Cu.

The second driving electrode layer 322 may be disposed below the first driving electrode layer 321 and may be connected to the driving device joint 330. The second driving electrode layer 322 may include at least one of Cu, Au, Ag, Al, and Ni. For example, an arbitrary region P2 of the second driving electrode layer 322 may include 80 wt % to 95 wt % of Ni and 5 wt % to 20 wt % of Cu. Such a second driving electrode layer 322 may include the same material as the first driving electrode layer 321. In other words, the second driving electrode layer 322 and the first driving electrode layer 321 may include Cu. As the second driving electrode layer 322 and the driving device joint 330 are connected to each other, a portion of components (e.g., Ni) included in the second driving electrode layer 322 may partially migrate toward the driving device joint 330. In this case, one region of the second driving electrode layer 322 may be formed as a layer including a portion of the components of the second driving electrode layer 322. Through this, bonding strength between the second driving electrode layer 322 and the driving device joint 330 may be improved.

The first driving device bonding layer 331 may be electrically connected to the substrate electrode 110. In other words, the first driving device bonding layer 331 may be disposed between the second driving device bonding layer 332 and the substrate electrode 110.

The first driving device bonding layer 331 may include a primary component having a predetermined fifth content and an additive element having a sixth content smaller than the fifth content. A weight percent (wt %) of the sixth content of the additive element in a composition ratio of the primary component and the additive element of such a first driving device bonding layer 331 may be greater than a weight percent of an eighth content of additive element in a composition ratio of a primary component and the additive element of the second driving device bonding layer 332 to be described later. A melting point of such a first driving device bonding layer 331 may be lower than a melting point of the second driving device bonding layer 332. For example, the melting point of the first driving device bonding layer 331 may be in a range of 110° C. to 190° C.

The first driving device bonding layer 331 may have a higher content of the additive elements than the second driving device bonding layer 332 such that a melting point of the first driving device bonding layer 331 is lower than a melting point of the second driving device bonding layer 332. The first driving device bonding layer 331 may include a primary component Sn and additive elements having a low melting point, such as Bi, In, Ag, or Pb. As a first example, the first driving device bonding layer 331 may be a metallic compound including 50 wt % to 65 wt % of Sn as a primary component and 35 wt % to 50 wt % of Bi as an additive element. As a second example, the first driving device bonding layer 331 may be a metallic compound including 46 wt % to 55 wt % of Sn as a primary component and 45 wt % to 54 wt % of In as an additive element. As a third example, the first driving device bonding layer 331 may be a metallic compound including 55 wt % to 65 wt % of Sn as a primary component and 35 wt % to 45 wt % of Pb as an additive element. Furthermore, a weight ratio of Bi or In and Sn of the first driving device bonding layer 331 may have different content ratios in arbitrary regions. For example, an arbitrary region P4 of the first driving device bonding layer 331 may include 80 wt % to 95 wt % of Bi and 5 wt % to 20 wt % of Sn. Furthermore, an arbitrary region P5 of the first driving device bonding layer 331 may include 2 wt % to 15 wt % of Bi and 85 wt % to 98 wt % of Sn. Furthermore, a content of Bi in the region P4 may be formed greater than a content of Bi in the region P5. A content of Sn in the region P4 may be formed smaller than a content of Sn in the region P5. A content of N in the region P4 may be formed smaller than a content of N in the region P5. Among such a first driving device bonding layer 331, the region P4 may be a first region disposed closer to the substrate 100 than the region P5. Furthermore, the region P5 may be a second region disposed closer to a center of the first driving device bonding layer 331 than the region P4.

The first driving device bonding layer 331 may extend in a vertical direction to cover at least a portion of an outer surface of the second driving device bonding layer 332. In other words, at least a portion of the second driving device bonding layer 332 may be disposed inside the first driving device bonding layer 331. Furthermore, an upper side of the first driving device bonding layer 331 may be in contact with the second driving electrode layer 322, but the present disclosure is not limited thereto, and the upper side of the first driving device bonding layer 331 may be disposed to be spaced apart from the second driving electrode layer 322.

The second driving device bonding layer 332 may be disposed between the first driving device bonding layer 331 and the control circuit layer 310. In other words, the second driving device bonding layer 332 may be stacked on the first driving device bonding layer 331. Furthermore, an upper side of the second driving device bonding layer 332 may be connected to the second driving electrode layer 322. The second driving device bonding layer 332 may include smaller additive components than the first driving device bonding layer 331. The second driving device bonding layer 332 may include a primary component having a predetermined seventh content and an additive element having an eighth content smaller than the seventh content. A weight percent of the eighth content of the additive element in a composition ratio of the primary component and the additive element of such a second driving device bonding layer 332 may be smaller than the weight percent of the sixth content of the additive element of the first driving device bonding layer 331.

Through this, the second driving device bonding layer 332 may have a melting point higher than the melting point of the first driving device bonding layer 331. For example, the melting point of the second driving device bonding layer 332 may be in a range of 210° C. to 280° C.

The second driving device bonding layer 332 may include a primary component of Sn or Au and additive elements of Pb, Sb, Ag, or Sn. As a first example, the second driving device bonding layer 332 may be a metal compound including 95 wt % to 97.5 wt % of a primary component Sn and 2 wt % to 3 wt % of an additive element Ag and 0.5 wt % to 2 wt % of an additive element Cu. As a second example, the second driving device bonding layer 332 may be a metal compound including 85 wt % to 95 wt % of a primary component Sn and 5 wt % to 15 wt % of an additive element Pb. As a third example, the second driving device bonding layer 332 may be a metal compound including 90 wt % to 97 wt % of a primary component Sn and 3 wt % to 10 wt % of an additive element Sb. As a fourth example, the second driving device bonding layer 332 may be a metal compound including 95 wt % to 98 wt % of a primary component Sn and 2 wt % to 5 wt % of an additive element Ag. As a fifth example, the second driving device bonding layer 332 may be a metal compound including 75 wt % to 85 wt % of a primary component Au and 15 wt % to 25 wt % of an additive element Sn.

An arbitrary region P3 of such a second driving device bonding layer 332 may include 1 wt % to 3 wt % of Si, 3 wt % to 5 wt % of Bi, and 85 wt % to 96 wt % of Sn. A content of the primary component Sn of the second driving device bonding layer 332 may be formed greater than the content of the primary component Sn of the first driving device bonding layer 331. Furthermore, a content of Bi of the additive elements in the first driving device bonding layer 331 may be greater than a content of Bi of the additive elements of the second driving device bonding layer 332.

Furthermore, at least a portion of the first driving device bonding layer 331, the second driving device bonding layer 332, and the driving electrode pad 320 may be formed continuously or integrally. In one example, the first driving device bonding layer 331 and the second driving device bonding layer 332 may be formed continuously or integrally. In another example, the first driving device bonding layer 331, the second driving device bonding layer 332, and the driving electrode pad 320 may be formed continuously or integrally.

Meanwhile, the plating layer 111 of the substrate electrode 110 may include at least one of Sn, Cu, W, Au, and Ag. For example, an arbitrary region P6 of the plating layer 111 may include 60 wt % to 90 wt % of Sn and 10 wt % to 40 wt % of Cu.

The substrate electrode 110 of the substrate 100 may include at least one of Cu, W, Au, and Ag. For example, an arbitrary region P7 of the substrate electrode 110 may include 90 wt % to 100 wt % of Cu.

The weight percent of the second content of the additive elements of the light emitting device joint 230 may be smaller than the weight percent of the sixth content of the additive elements included in the first driving device bonding layer 331. A melting point of such a light emitting device joint 230 may be higher than the first driving device bonding layer 331, and may be identical to the melting point of the second driving device bonding layer 332.

The light emitting device joint 230 may include a primary component Au or Sn and at least one of additive elements Pb, Sb, Ag, Cu, and Sn to form the melting point of the light emitting device joint 230 higher than the melting point of the first driving device bonding layer 331. As a first example, the light emitting device joint 230 may be a metal compound including 95 wt % to 97.5 wt % of a primary component Sn and 2 wt % to 3 wt % of an additive element Ag and 0.5 wt % to 2 wt % of an additive element Cu. As a second example, the light emitting device joint 230 may be a metal compound including 85 wt % to 95 wt % of a primary component Sn and 5 wt % to 15 wt % of an additive element Pb. As a third example, the light emitting device joint 230 may be a metal compound including 90 wt % to 97 wt % of a primary component Sn and 3 wt % to 10 wt % of an additive element Sb. As a fourth example, the light emitting device joint 230 may be a metal compound including 95 wt % to 98 wt % of a primary component Sn and 2 wt % to 5 wt % of an additive element Ag. As a fifth example, the light emitting device joint 230 may be a metal compound including 75 wt % to 85 wt % of a primary component Au and 15 wt % to 25 wt % of an additive element Sn.

Hereinafter, an operation and an effect of the light emitting module 10 according to the second embodiment of the present disclosure and the light emitting system 1 including the same will be described.

When a temperature of heat applied to the driving device 300 of the light emitting module 10 according to the second embodiment is lower than the melting point of the second driving device bonding layer 332 and equal to or higher than the melting point of the first driving device bonding layer 331, heat transfer to the driving device 300 by the second driving device bonding layer 332 may be prevented, thereby protecting the driving device 300.

Furthermore, when the temperature of the applied heat is lower than the melting point of the second driving device bonding layer 332 and equal to or higher than the melting point of the first driving device bonding layer 331, the driving device 300 may be detached from the substrate 100, thereby facilitating repair.

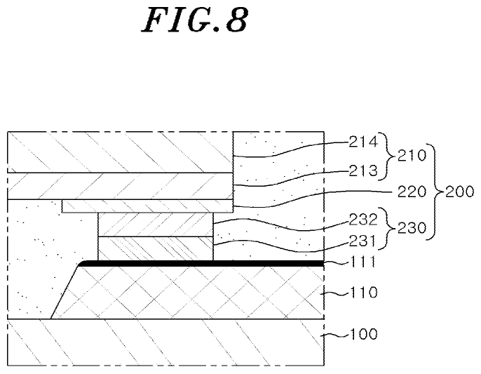

Hereinafter, referring to FIG. 8, the light emitting module 10 according to a third embodiment of the present disclosure and the light emitting system 1 including the same will be described.

In describing the third embodiment, there is a difference in that the light emitting device joint 230 may include a first light emitting device bonding layer 231 and a second light emitting device bonding layer 232, and the description will focus on such differences.

The first light emitting device bonding layer 231 may be connected to the substrate electrode 110. In other words, the first light emitting device bonding layer 231 may be disposed between the second light emitting device bonding layer 232 and the substrate 100. The first light emitting device bonding layer 231 may include a primary component having a predetermined ninth content and additive elements having a tenth content smaller than the ninth content. A weight percent of the tenth content of the additive elements of such a first light emitting device bonding layer 231 may be greater than a weight percent of a twelfth content of additive elements of the second light emitting device bonding layer 232 to be described later. A melting point of such a first light emitting device bonding layer 231 may be lower than a melting point of the second light emitting device bonding layer 232. For example, the melting point of the first light emitting device bonding layer 231 may be in a range of 110° C. to 190° C.

The first light emitting device bonding layer 231 may include a primary component Sn and additive elements Bi, In, or Pb to form the melting point of the first light emitting device bonding layer 231 lower than the melting point of the second light emitting device bonding layer 232. As a first example, the first light emitting device bonding layer 231 may be a metal compound including 50 wt % to 65 wt % of a primary component Sn and 35 wt % to 50 wt % of an additive element Bi. As a second example, the first light emitting device bonding layer 231 may be a metal compound including 46 wt % to 55 wt % of a primary component Sn and 45 wt % to 54 wt % of an additive element In. As a third example, the first light emitting device bonding layer 231 may be a metal compound including 55 wt % to 65 wt % of a primary component Sn and 35 wt % to 45 wt % of an additive element Pb.

Furthermore, a content of In or Bi in the first light emitting device bonding layer 231 may be formed greater than a content of In or Bi in the second light emitting device bonding layer 232.

Furthermore, the first light emitting device bonding layer 231 may be formed to be spaced apart from the light emitting electrode pad 220, but the present disclosure is not limited thereto. In other words, the first light emitting device bonding layer 231 may extend in a vertical direction to covering at least a portion of an outer surface of the second light emitting device bonding layer 232, such that at least a portion of the second light emitting device bonding layer 232 is disposed inside.

The second light emitting device bonding layer 232 may be disposed between the first light emitting device bonding layer 231 and the light emitting layer 210. In other words, the second light emitting device bonding layer 232 may be stacked on the first light emitting device bonding layer 231. Furthermore, an upper side of the second light emitting device bonding layer 232 may be connected to the light emitting electrode pad 220.

The second light emitting device bonding layer 232 may include a primary component having an eleventh content and additive elements having a twelfth content smaller than the eleventh content. A weight percent (wt %) of the twelfth content of the additive elements of the second light emitting device bonding layer 232 may be smaller than the weight percent of the tenth content of the additive elements of the first light emitting device bonding layer 231. Such a second light emitting device bonding layer 232 may have a melting point higher than the melting point of the first light emitting device bonding layer 231. The melting point of the second light emitting device bonding layer 232 may be in a range of 210° C. to 280° C.

The second light emitting device bonding layer 232 may include a primary component Au or Sn and at least one of additive elements Pb, Sb, Ag, Cu, and Sn. As a first example, the second light emitting device bonding layer 232 may be a metal compound including 95 wt % to 97.5 wt % of a primary component Sn and 2 wt % to 3 wt % of an additive element Ag and 0.5 wt % to 2 wt % of an additive element Cu. As a second example, the second light emitting device bonding layer 232 may be a metal compound including 85 wt % to 95 wt % of a primary component Sn and 5 wt % to 15 wt % of an additive element Pb. As a third example, the second light emitting device bonding layer 232 may be a metal compound including 90 wt % to 97 wt % of a primary component Sn and 3 wt % to 10 wt % of an additive element Sb. As a fourth example, the second light emitting device bonding layer 232 may be a metal compound including 95 wt % to 98 wt % of a primary component Sn and 2 wt % to 5 wt % of an additive element Ag. As a fifth example, the second light emitting device bonding layer 232 may be a metal compound including 75 wt % to 85 wt % of a primary component Au and 15 wt % to 25 wt % of an additive element Sn.

Furthermore, a content of Sn of the second light emitting device bonding layer 232 may be formed greater than a content of Sn of the first light emitting device bonding layer 231.

Meanwhile, the weight percent of the fourth content of the additive elements of the driving device joint 330 may be smaller than the weight percent of the tenth content of the additive elements of the first light emitting device bonding layer 231.

A melting point of such a driving device joint 330 may be identical to the melting point of the second light emitting device bonding layer 232 or higher than the melting point of the first light emitting device bonding layer 231. The melting point of the driving device joint 330 may be in a range of 210° C. to 280° C.

The driving device joint 330 may include a primary component Au or Sn and at least one of additive elements Pb, Sb, Ag, Cu, and Sn. As a first example, the driving device joint 330 may be a metal compound including 95 wt % to 97.5 wt % of a primary component Sn and 2 wt % to 3 wt % of an additive element Ag and 0.5 wt % to 2 wt % of an additive element Cu. As a second example, the driving device joint 330 may be a metal compound including 85 wt % to 95 wt % of a primary component Sn and from 5 wt % to 15 wt % of an additive element Pb. As a third example, the driving device joint 330 may be a metal compound including 90 wt % to 97 wt % of a primary component Sn and 3 wt % to 10 wt % of an additive element Sb. As a fourth example, the driving device joint 330 may be a metal compound including 95 wt % to 98 wt % of a primary component Sn and 2 wt % to 5 wt % of an additive element Ag. As a fifth example, the driving device joint 330 may be a metal compound including 75 wt % to 85 wt % of a primary component Au and 15 wt % to 25 wt % of an additive element Sn.

Hereinafter, an operation and an effect of the light emitting module 10 according to the third embodiment of the present disclosure and the light emitting system 1 including the same will be described.

When a temperature of heat applied to the light emitting device 200 of the light emitting module 10 according to the third embodiment is lower than the melting point of the second light emitting device bonding layer 232 and higher than the melting point of the first light emitting device bonding layer 231, heat transfer to the light emitting device 200 by the second light emitting device bonding layer 232 may be prevented, thereby protecting the light emitting device 200.

Furthermore, when the temperature of the applied heat is lower than the melting point of the second light emitting device bonding layer 232 and higher than the melting point of the first light emitting device bonding layer 231, the light emitting device 200 may be detached from the substrate 100, thereby facilitating repair.

The examples of the present disclosure have been described above as specific embodiments, but these are only examples, and the present disclosure is not limited thereto, and should be construed as having the widest scope according to the technical spirit disclosed in the present specification. A person skilled in the art may combine/substitute the disclosed embodiments to implement a pattern of a shape that is not disclosed, but it also does not depart from the scope of the present disclosure. In addition, those skilled in the art can easily change or modify the disclosed embodiments based on the present specification, and it is clear that such changes or modifications also belong to the scope of the present disclosure.

[Description of Reference Numerals]

```
    1: light emitting system
  10: light emitting module
  20: frame
100: substrate
110: substrate electrode
111: plating layer
200: light emitting device
210: light emitting layer
211: first conductivity type semiconductor layer
212: active layer
213: second conductivity type semiconductor layer
220: light emitting electrode pad
230: light emitting device joint
231: first light emitting device bonding layer
232: second light emitting device bonding layer
240: light transmitting layer
300: driving device
310: control circuit layer
320: driving electrode pad
321: first driving electrode layer
322: second driving electrode layer
330: driving device joint
331: first driving device bonding layer
332: second driving device bonding layer
400: molding layer
```

1. A light emitting module comprising:
a substrate;
a light emitting device disposed on the substrate; and
a driving device disposed on the substrate,
wherein the light emitting device includes:
a light emitting layer configured to generate light; and
a light emitting device joint disposed between the light emitting layer and the substrate to fix the light emitting layer to the substrate,
wherein the driving device includes:
a control circuit layer configured to control the light emitting device; and
a driving device joint disposed between the control circuit layer and the substrate to fix the control circuit layer to the substrate,
wherein the light emitting device joint includes a primary component having a predetermined content and additive elements having a content smaller than the content of the primary component,
wherein the driving device joint includes a primary component having a predetermined content and additive elements having a content smaller than the content of the primary component, and
wherein a content of the additive elements included in the light emitting device joint is different from a content of the additive elements included in the driving device joint.

2. The light emitting module of claim 1, wherein the content of the additive elements included in the light emitting device joint is greater than the content of the additive elements included in the driving device joint.

3. The light emitting module of claim 2, wherein the primary component of the light emitting device joint includes Sn, the additive elements of the light emitting device joint include Bi, the primary component of the driving device joint includes Sn, and the additive elements of the driving device joint include Ag and Cu.

4. The light emitting module of claim 2, wherein a melting point of the light emitting device joint is lower than a melting point of the driving device joint.

5. The light emitting module of claim 1, wherein the content of the additive elements included in the light emitting device joint is smaller than the content of the additive elements included in the driving device joint.

6. The light emitting module of claim 5, wherein the primary component of the light emitting device joint includes Au, the additive elements of the light emitting device joint include Sn, the primary component of the driving device joint includes Sn, and the additive elements of the driving device joint include Bi.

7. The light emitting module of claim 5, wherein the primary component of the light emitting device joint includes Sn, the additive elements of the light emitting device joint include Ag and Cu, the primary component of the driving device joint includes Sn, and the additive elements of the driving device joint include Bi.

8. The light emitting module of claim 5, wherein a melting point of the light emitting device joint is higher than a melting point of the driving device joint.

9. The light emitting module of claim 1, wherein a thermal conductivity of the light emitting device joint and a thermal conductivity of the driving device joint are different from each other.

10. A light emitting module comprising:
a substrate;
a light emitting device disposed on the substrate and configured to emit light; and
a driving device disposed on the substrate,
wherein the driving device includes:
a control circuit layer configured to control the light emitting device; and
a driving device joint disposed between the control circuit layer and the substrate to fix the control circuit layer to the substrate,
wherein the driving device joint includes:
a first driving device bonding layer connected to the substrate; and
a second driving device bonding layer disposed between the first driving device bonding layer and the control circuit layer,
wherein the first driving device bonding layer includes a primary component having a predetermined content and additive elements having a predetermined content,
wherein the second driving device bonding layer includes a primary component having a predetermined content and additive elements having a predetermined content, and
wherein a content of the additive elements included in the first driving device bonding layer is greater than a content of the additive elements included in the second driving device bonding layer.

11. The light emitting module of claim 10, wherein the first driving device bonding layer surrounds at least a portion of the second driving device bonding layer.

12. The light emitting module of claim 11, wherein the driving device further includes a driving electrode pad disposed between the control circuit layer and the driving device joint, and an upper side of the first driving device bonding layer and an upper side of the second driving device bonding layer are in contact with the driving electrode pad.

13. The light emitting module of claim 10, wherein the first driving device bonding layer and the second driving device bonding layer are formed integrally.

14. The light emitting module of claim 10, wherein the primary component of the second driving device bonding layer includes Sn, the additive elements of the second driving device bonding layer include at least one of Ag, Cu, Pb, and Sb, the primary component of the first driving device bonding layer includes Sn, and the additive elements of the first driving device bonding layer include Bi, In, or Pb.

15. The light emitting module of claim 10, wherein a melting point of the first driving device bonding layer is lower than a melting point of the second driving device bonding layer.

16. The light emitting module of claim 14, wherein a content of Sn in the first driving device bonding layer is smaller than a content of Sn in the second driving device bonding layer.

17. The light emitting module of claim 10, wherein the light emitting device comprises:
a light emitting layer configured to generate; and
a light emitting device joint disposed between the light emitting layer and the substrate to fix the light emitting layer to the substrate,
wherein the light emitting device joint includes a primary component having a predetermined content and additive elements having a predetermined content, and
wherein the content of the additive elements included in the first driving device bonding layer is greater than a content of the additive elements included in the light emitting device joint.

18. The light emitting module of claim 10, wherein the driving device further includes a driving electrode pad disposed between the control circuit layer and the first driving device bonding layer,
wherein the driving electrode pad includes:
a first driving electrode layer connected to the control circuit layer; and
a second driving electrode layer disposed below the first driving electrode layer and in contact with the second driving device bonding layer, and
wherein the second driving device bonding layer and the second driving electrode layer include a same material.

19. A light emitting module comprising:
a substrate; and
a light emitting device disposed on the substrate,
wherein the light emitting device includes:
a light emitting layer configured to generate light; and
a light emitting device joint disposed between the light emitting layer and the substrate to fix the light emitting layer to the substrate,
wherein the light emitting device joint includes:
a first light emitting device bonding layer disposed on the substrate; and
a second light emitting device bonding layer disposed between the first light emitting device bonding layer and the light emitting layer,
wherein the first light emitting device bonding layer includes a primary component having a predetermined content and additive elements having a predetermined content,
wherein the second light emitting device bonding layer includes a primary component having a predetermined content and additive elements having a predetermined content, and
wherein a content of the additive elements included in the first light emitting device bonding layer is greater than a content of the additive elements included in the second light emitting device bonding layer.

20. The light emitting module of claim 19, further comprising:
a driving device disposed on the substrate,
wherein the driving device includes:
a control circuit layer configured to control the light emitting device; and
a driving device joint disposed between the control circuit layer and the substrate to fix the control circuit layer to the substrate,
wherein the driving device joint includes a primary component having a predetermined content and additive elements having a predetermined content, and
wherein the content of the additive elements included in the first light emitting device bonding layer is greater than a content of the additive elements included in the driving device joint.
